(19) United States
(12) Patent Application Publication
(10) Pub. No.: US 2015/0061711 A1
(43) Pub. Date: Mar. 5, 2015

(54) Overclocking as a Method for Determining Age in Microelectronics for Counterfeit Device Screening

(71) Applicant: United States of America as represented by the Secretary of the Navy, Crane, IN (US)

(72) Inventor: Brett Hamilton, Heltonville, IN (US)

(21) Appl. No.: 14/451,012

(22) Filed: Aug. 4, 2014

Related U.S. Application Data
(60) Provisional application No. 61/873,061, filed on Sep. 3, 2013.

(51) Int. Cl. G01R 31/28

(52) U.S. Cl. CPC G01R 31/2855; G01R 31/2882
USPC 324/750.05

(57) ABSTRACT

An invention employing testing, e.g., overclocking, to determine undesirable conditions in a device under test (DUT) is provided. An exemplary apparatus and method includes artificially aging a known sample microelectronic device (SMD); overclocking the known SMD to specification and/or maximum performance; and collecting a plurality of device data associated with overclocking of each SMD at multiple ageing data points over a predicted aging progression. Another exemplary next step includes overclocking a DUT and collecting device data associated with the overclocked DUT. Another exemplary next step includes comparing the DUT device data with SMD device data to determine, for example, if the DUT has an anomaly or undesirable condition, if the DUT conforms to a manufacturer's specification, if the DUT was made by an original equipment manufacturer, if the DUT is used but represented as new, and/or the DUT has been subjected to damage or stress events exceeding acceptable limits.

### CROSS-REFERENCE TO RELATED APPLICATIONS

The present application claims priority to U.S. Provisional Patent Application Ser. No. 61/873,061, filed Sep. 3, 2013, entitled “OVERCLOCKING AS A METHOD FOR DETERMINING AGE IN MICROELECTRONICS FOR COUNTERFEIT DEVICE SCREENING,” the disclosure of which is expressly incorporated by reference herein.

### STATEMENT REGARDING FEDERALLY SPONSORED RESEARCH OR DEVELOPMENT

The invention described herein was made in the performance of official duties by employees of the Department of the Navy and may be manufactured, used and licensed by or for the United States Government for any governmental purpose without payment of any royalties thereon. This invention (Navy Case 102,783) is assigned to the United States Government and is available for licensing for commercial purposes. Licensing and technical inquiries may be directed to the Technology Transfer Office, Naval Surface Warfare Center Crane, email: Cran_CTO@navy.mil.

### BACKGROUND AND SUMMARY OF THE INVENTION

The present invention generally is directed to analytics, processes, and apparatuses associated with testing or verification activities associated with electronic devices. For example, one embodiment of the invention relates sensing and detection of a Known Good Device Under Test (KGDUT) used in relation to testing associated with a Device Under Testing (DUT) in order to detect electrical or other characteristics associated with defective or unauthorized items in a supply chain using, for example, overclocking methods. Defects or unauthorized status can include parts that do not conform to their specifications, are not authorized by an original equipment manufacturer, a case where a used part is being passed off as a new part, or a case where a part or component has been subjected to one or more damage or stress events exceeding acceptable limits such as electrostatic discharge (ESD) events. System defect or supply chain problem detection is increasingly more difficult given large volumes, difficulty in accessing parts in an assembly, and different sizes, shapes, and input/output structure, particularly for mass produced parts or defect detection for parts that have left a factory.

A common problem with existing methods for detecting defective or unauthorized items in a supply chain is the difficulty and cost of implementing a detection system. This is especially true for already produced microelectronics. Many counterfeit detections systems require the insertion of specialized circuitry or at-speed functional based timing tests for already produced microelectronics. Newer microelectronics have ring oscillators built in. These ring oscillators provide a reliable testing point for consumers to determine if the microelectronics conform to their specifications, are not authorized by an original equipment manufacturer, a case where a used part is being pass off as a new part, or a case where a part/component has been subjected to one or more damage or stress events exceeding acceptable limits such as ESD events. While this approach may be effective for newer microelectronics, it is not always effective for ones already produced.

Another common problem with existing methods for detecting defective or unauthorized items in a supply chain is the unavailability of detailed data from the manufacture regarding, for example, test vectors and timing details. As transistors age, their transition speed decreases. The decrease in speed can be measured with traditional electrical tests and compared to the manufacturer's specific, new product details. However, such detailed data either does not exist or is not provided for commercial off the shelf parts.

One embodiment of the invention uses multiple test detection and data collection/input modes coupled with one or more decision engines such as neural networks, image recognition, statistical correlation tools, and decision trees, which can incorporate various learning processes. Another embodiment can also include a data collection system with one embodiment including electromagnetic (EM) sensors and data collection inputs adapted to sense test data and input the data into an embodiment of the multiple mode analysis decision engine to evaluate a DUT system. For example, an embodiment of the invention can incorporate integration of multiple EM sensors as well as data inputs and in synchronization with DUT stimulation for the purpose of producing device unique EM signatures accompanied by a decision engine, including a neural engine, to provide a variety of novel embodiments of the invention to meeting a variety of supply chain item defect or unauthorized item detection needs.

An exemplary embodiment can have an Automatic Testing Equipment (ATE) applying an exemplary high-speed stimulus to a DUT and measure the response of the DUT. An exemplary response can result in multiple electrical characteristic modalities data sets. An exemplary data set can be used for the purpose of determining a probability that a microelectronic conforms to their specifications, are not authorized by an original equipment manufacturer, a case where a used part is being passed off as a new part, or a case where a part or component has been subjected to one or more damage or stress events exceeding acceptable limits such as electrostatic discharge (ESD) events.

An exemplary response from the DUT can be, for example, a single pass/fail value, e.g. maximum frequency. Another example of an exemplary response from the DUT can be, for example, a plurality of data which could be put into a Shmoo plot. One variant of a Shmoo plot can be shown in a graphical display of a response of a component or system varying over a range of conditions and inputs. A Shmoo plot can be used to represent results of testing of complex electronic systems such as computers or integrated circuits such as memory devices, application specific integrated circuits, or microprocessors. A Shmoo plot can show a range of conditions in which a DUT operates including operation in adherence with a set of specifications. For example, when testing semiconductor memory: voltages, temperature, and refresh rates can be varied over specified ranges and only certain combinations of these factors will allow the device to operate. In one example, plotted on independent axes (voltage, temperature, refresh rates), a range of working values could enclose a three-dimensional shape, including, e.g., an oddly-shaped volume. Other examples of conditions and inputs that can be varied include frequency, temperature, timing parameters, system- or component-specific variables, and even varying test settings tweakable during silicon chip fabrication producing parts of varying quality which are then used in a manufacturing or testing process. In one embodiment, one setting or variable can be plotted on one axis against another setting or variable on another axis, producing a two dimensional graph. This allows a test engineer to visually observe operating ranges of a DUT.

In one embodiment of the invention, an exemplary Shmoo plot would compare an exemplary plurality of data from a DUT to a plurality of KGDUT data. Some examples of KGDUT include a Golden Device, which, for example, may be a KGDUT which has undergone controlled accelerated age testing to establish baseline reference data. Another example of KGDUT includes a KGDUT which has been sacrificed from the procurement lot of similar DUT and exposed to controlled, accelerated aging.

An exemplary high-speed stimulus, e.g., overclocking of KGDUTs and test articles devices under testing (TADUT) in various scenarios including ageing, can be applied to various components or areas of areas of interest such as, e.g., common data ports, for example, Serial Peripheral Interface (SPI) Bus, Inter-Integrated Circuit (I²C), RS232 Standard Ports (RS232), and Joint Test Action Group (JTAG). Exemplary high-speed stimuli can also be applied via bus protocols and used in conjunction with basic timing information. This exemplary application greatly simplifies test set-up requirements, causing a reduction in both time and money normally needed.

Additional features and advantages of the present invention will become apparent to those skilled in the art upon consideration of the following detailed description of the illustrative embodiment exemplifying the best mode of carrying out the invention as presently perceived.

### BRIEF DESCRIPTION OF THE DRAWINGS

FIG. 1 shows an exemplary schematic diagram of one aspect of one example embodiment of the invention;

FIG. 2 shows a high-speed stimulus being provided to a DUT, and the response being measure by the ATE;

FIG. 3 shows and example of a Shmoo plot with black showing the parameters for a passing TADUT, and white showing the parameters of a failing TADUT;

FIG. 4 shows an exemplary diagram for the process of using overclocking as a method for determining age microelectronics for counterfeit device screening;

FIG. 5 shows a sample boxplot;

FIG. 6 shows an exemplary boxplot displaying a percentage change in initial measurements of an exemplary DUT at five hundred hours by row;

FIG. 7 shows an exemplary boxplot displaying a percentage change in initial measurement at five hundred hours by row (columns 0-5 separate);

FIG. 8 shows an exemplary boxplot displaying percentage change in initial measurements at five hundred hours by row (columns 6-11 separate);

FIG. 9 shows an exemplary boxplot displaying percentage change in initial measurements at five hundred hours by row (columns 12-15 separate);

FIG. 10 shows an exemplary boxplot displaying percentage change in initial measurements at five hundred hours by column (rows 0-3 separate);

FIG. 11 shows an exemplary boxplot displaying percentage change in initial measurements at five hundred hours by column (rows 4-7 separate);

FIG. 12 shows an exemplary boxplot displaying five hundred hour measurements vs zero hour measurements;

FIG. 13 shows an exemplary boxplot displaying a delta of five hundred hours minus zero hour measurements;

FIG. 14 shows an exemplary delta of 500 hours minus zero Hour Measurements by column (each row separate);

FIG. 15 shows an exemplary manufacturer data sheet with maximum operating frequency and critical timing parameters;

FIG. 16 shows an exemplary manufacturer data sheet with varying maximum operating frequency based on device speed grade;

FIG. 17 shows an exemplary flow for creating boxplots;

FIG. 18 shows an exemplary flow for using Shmoo diagrams to optimize timing for measuring DUT maximum operating frequency; and

FIG. 19 shows another testing analysis result showing how an embodiment of the invention can be used to detect a predetermined condition such as counterfeit parts.

### DETAILED DESCRIPTION OF THE DRAWINGS

The embodiments of the invention described herein are not intended to be exhaustive or to limit the invention to precise forms disclosed. Rather, the embodiments selected for description have been chosen to enable one skilled in the art to practice the invention.

One aspect of the invention can create multiple electrical characteristic modalities and data sets for the purpose of determining a probability that a DUT, e.g., a microelectronic device conforms to their specifications, are not authorized by an original equipment manufacturer, a case where a used part is being passed off as a new part, or a case where a part or component has been subjected to one or more damage or stress events exceeding acceptable limits such as ESD events. Application of multiple data sets can enable a high accuracy probability determination of a particular condition or status associated with a DUT such as discussed above. For example, transistors incorporated in microelectronic devices decrease in their speed of operation with age. By comparing the speed of operation of a KGDUT to the speed of operation of a DUT, and other data, the age of the DUT can be determined.

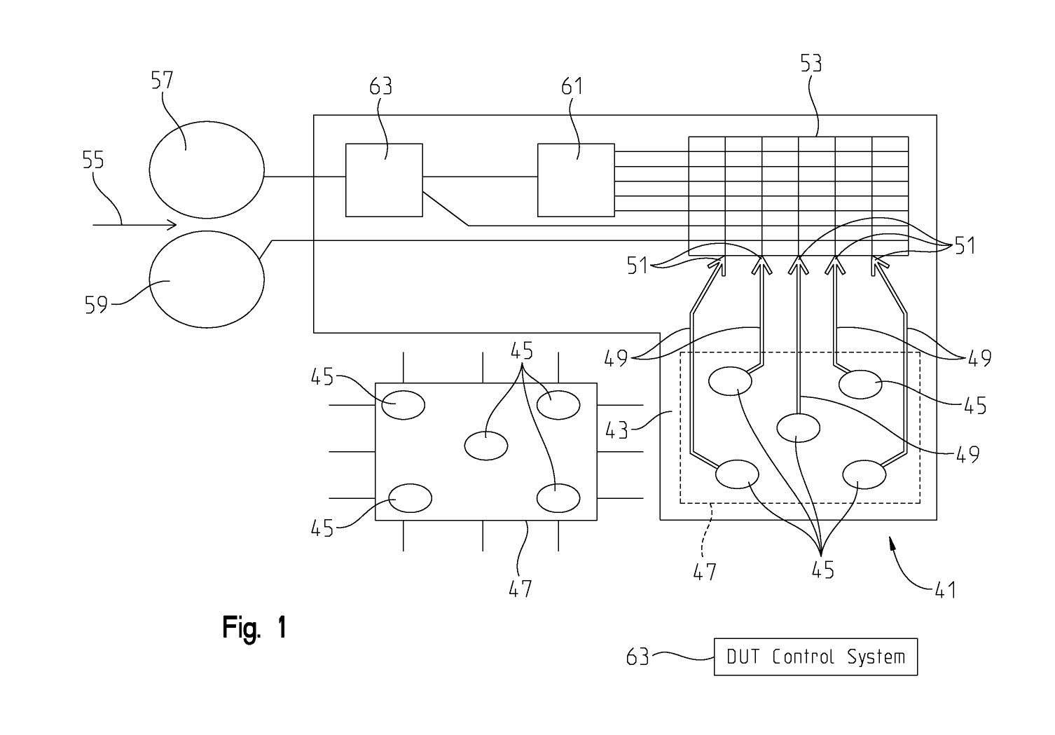

FIG. 1 shows an exemplary schematic diagram of one aspect of one example embodiment of the ATE where overclocking as a method for determining age in microelectronics for counterfeit device screening could be used. A DUT testing assembly 41 is shown which includes a support fixture 43 which supports or positions EM sensors, e.g. EM probes, 45 positioned over a DUT 47. Signal paths 49 connect EM sensors 45 with amplifiers 51. Amplifiers 51 are coupled with a signal analysis section 55 which provides signal analysis in a time domain and/or a frequency domain. For example, amplifiers 51 can be coupled with a signal analysis section 55 comprising a signal analyzer 57 and an oscilloscope 59 via a switch matrix 53. Separate connections (not shown) to the signal analysis section 55 can be used or a summing section 61 can be used which combines output from one or more amplifiers into a composite signal for input into the signal analysis section 55. A switch 63 can be interposed between the signal analysis section 55 and the summing section 61. The EM sensors 45 can be adapted to be repositionable or movable to be placed over specific areas of interest of a particular DUT 47.

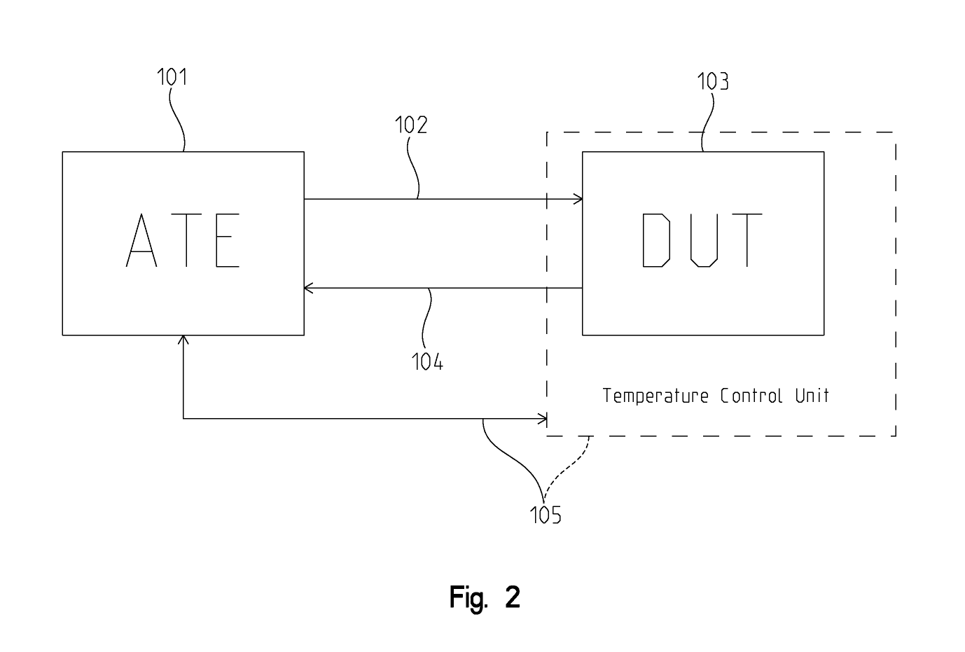

FIG. 2 shows diagram of high-speed stimulus 102 provided by the ATE 101, as described in FIG. 1 above, and the response 104 by the DUT 103. An example of high-speed stimulus 102 would be an electrical signal. An exemplary electrical signal can be applied to, for example, the DUT's JTAG port. An exemplary response, for example, in the form of a plurality data, will be sent from the exemplary DUT to the exemplary ATE. There, exemplary data can be, for example, a single pass/fail value, e.g. maximum frequency. DUT temperature can be very accurately maintained during evaluation using an external heating and cooling apparatus with real-time feedback 105.

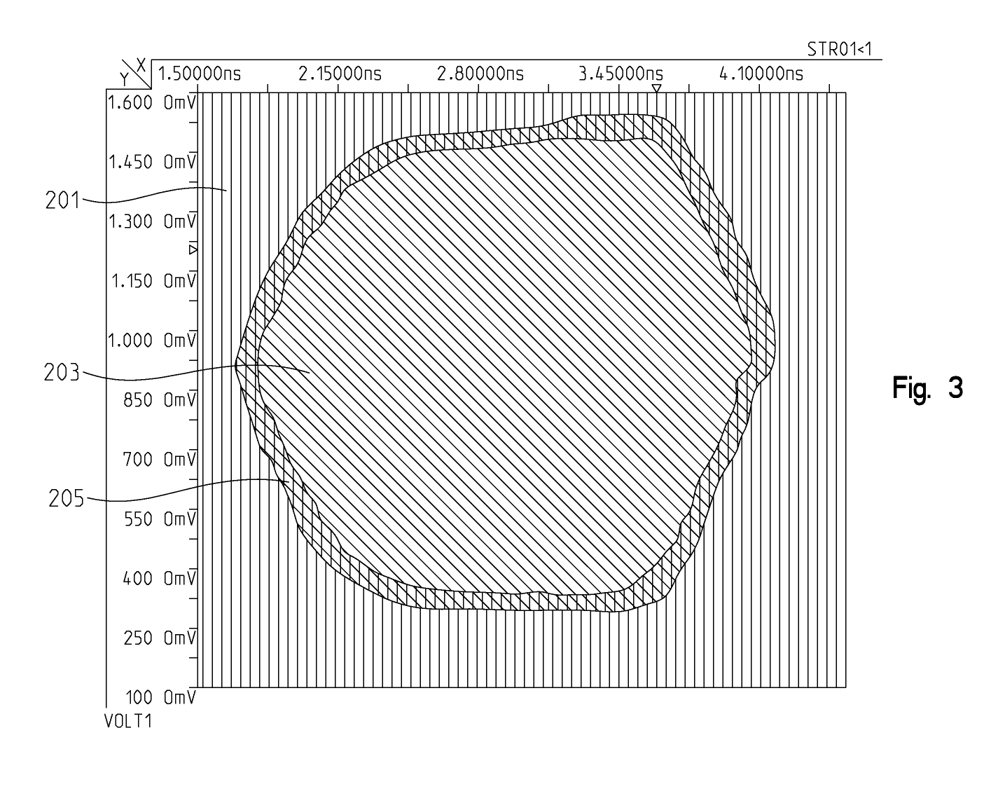

FIG. 3 shows an example of a Shmoo plot. This exemplary Shmoo plot could be created from an exemplary ATE's interpretation or representation of an exemplary response containing a plurality of data. Exemplary data points (EDP) 201 would be interpreted as the exemplary DUT failing to meet ATE standards for acceptable DUTs. EDPs 205 can be interpreted as an exemplary DUT meeting ATE standards for acceptable DUTs. EDPs 205 may require further input as the exemplary data points neither pass, nor fail the ATE standards.

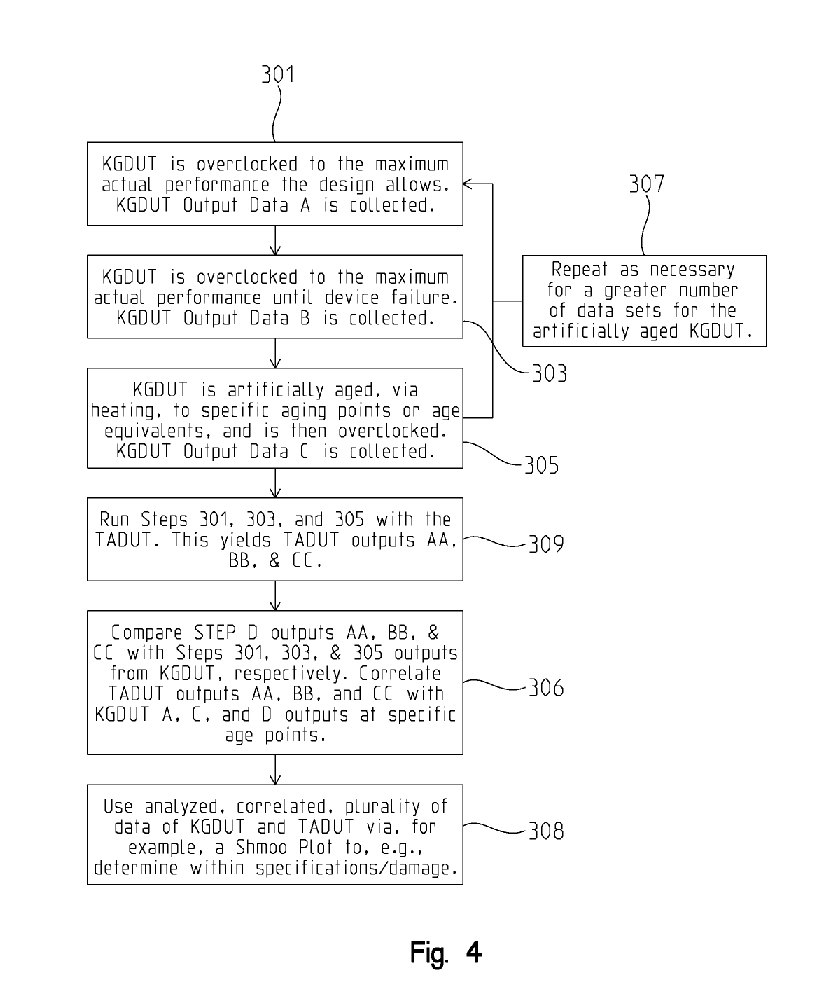

FIG. 4 shows an exemplary method for using overclocking as a method for determining age in microelectronics for counterfeit device screening. In Step 301, an exemplary KGDUT is overclocked to the maximum actual performance design allows. In Step 303, the exemplary KGDUT is overclocked to maximum actual performance until the exemplary KGDUT fails. In Step 305, the exemplary KGDUT is artificially aged via heating to specific aging points or age equivalents. Steps 301, 303, and 305 are repeated as necessary for greater artificially aged KGDUTs at step 307. In Step 309, Steps 301, 303, and 305 are run with the exemplary TADUT to produce outputs AA, BB, and CC. In Step 306, Step 309 outputs are compared to the outputs from their respective outputs from the exemplary KGDUT (e.g., A, B, and C) at specific aged points. In Step 307, the analysed and correlated data of the exemplary KGDUT and exemplary TADUT are combined in, for example, a Shmoo plot similar to that of FIG. 3, to determine if the exemplary TADUT conforms to their specifications, are not authorized by an original equipment manufacturer, a case where a used part is being passed off as a new part, or a case where a part or component has been subjected to one or more damage or stress events exceeding acceptable limits such as ESD events.

The temperature of the KGDUT/DUT must be controlled in both clocking and overclocking, as too high of a temperature can damage the KGDUTs/DUTs and shift response. One possibility of controlling temperature is applying some sort of cooling system is, for example, to place the entire DUT testing assembly (e.g., ATE), including the exemplary KGDUT/DUT, into a sealed tank or use a forced air temperature control system. The exemplary sealed tank would then be filled with a non-conductive liquid to act as a heat sink for the exemplary KGDUT/DUT.

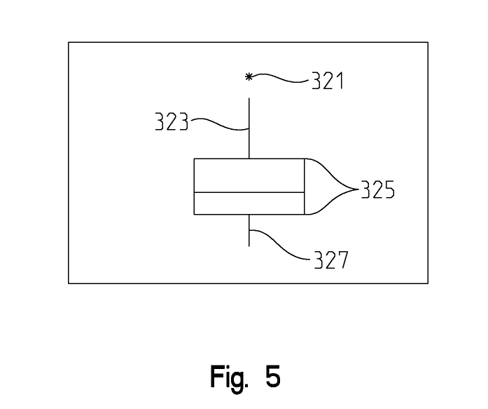

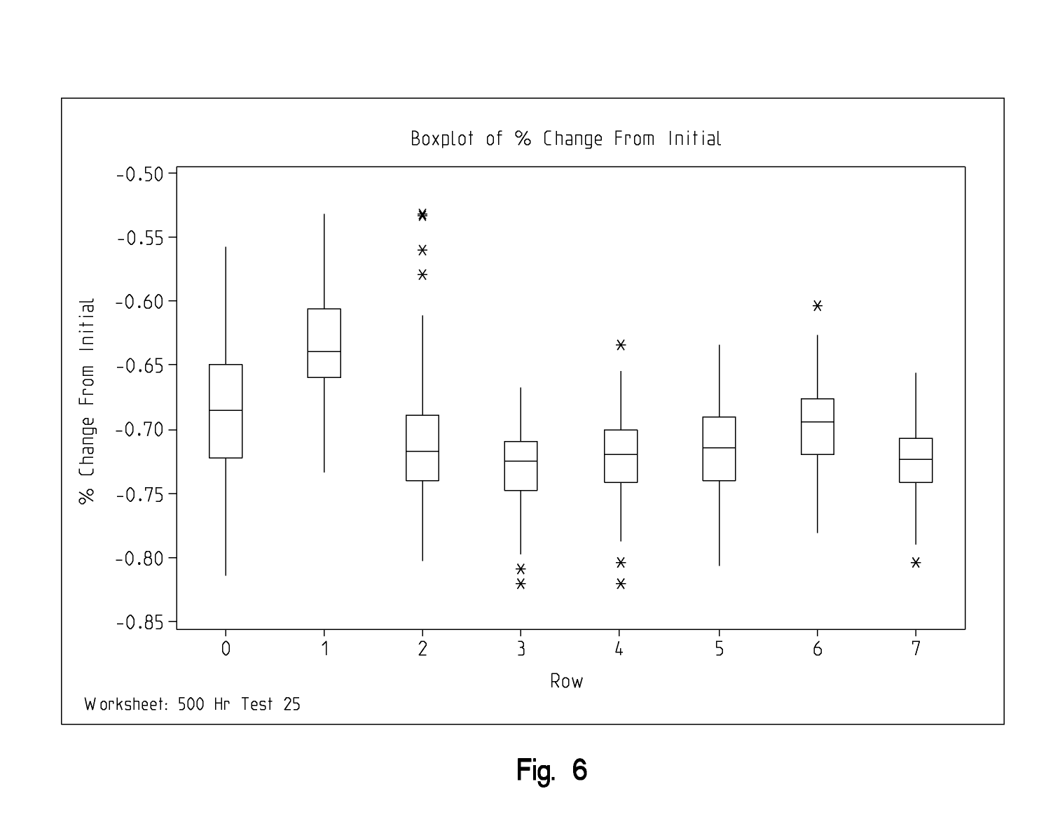

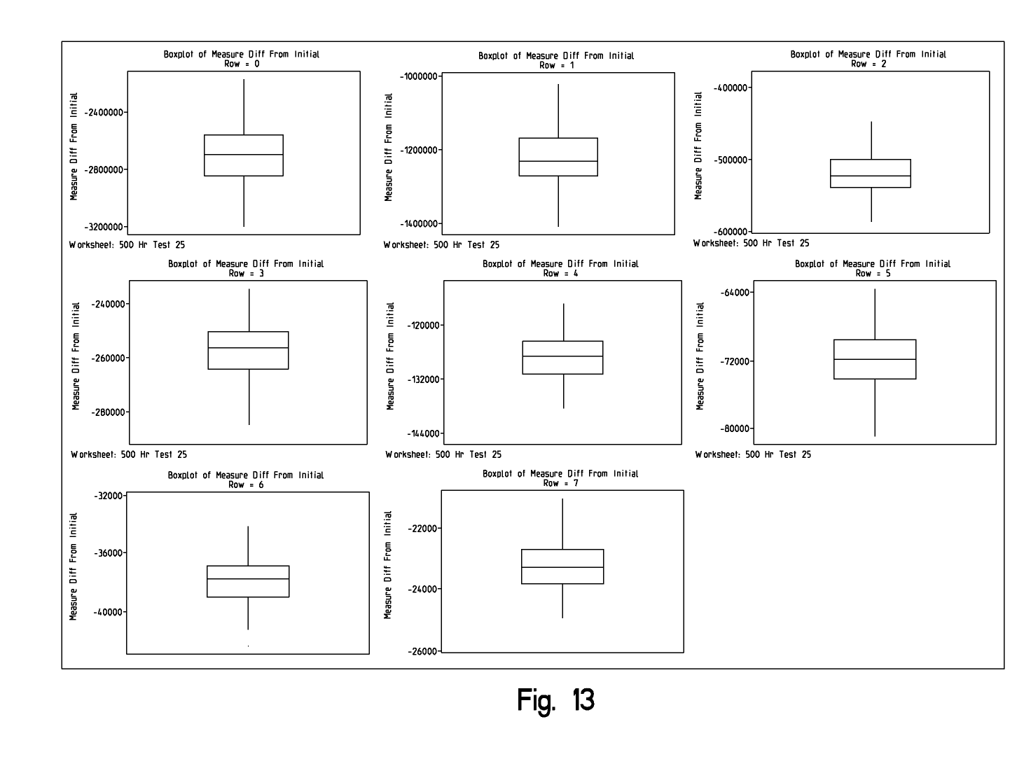

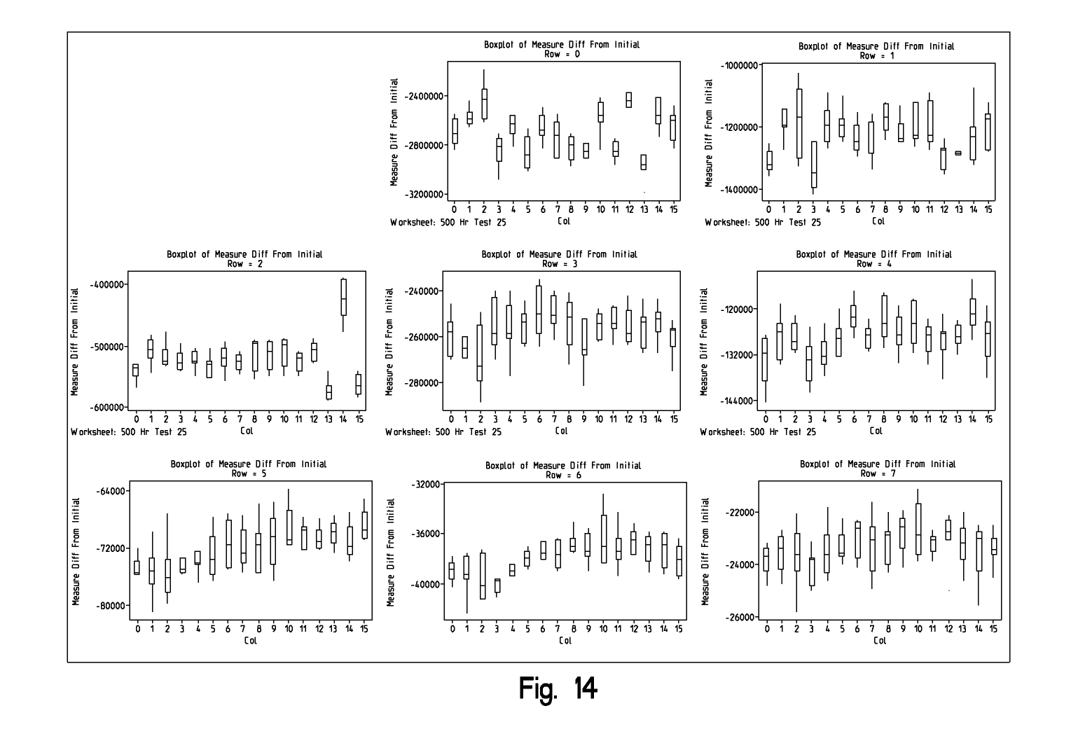

FIG. 5 shows a generic exemplary output from one embodiment of the invention comprising of a boxplot. A specific variant of this boxplot can include showing a shift in values of frequency from initial values to values taken after a specified number of hours for a DUT. A boxplot can provide a graphical summary of a distribution of a sample that shows its shape, central tendency, and variability. Boxplots can show shifts in values of frequency from initial values to values taken after a specific number of hours, e.g., 500 hours, for a DUT e.g., an oscillator. Of particular interest is an observation of one application of the invention is that regardless of location (row or column) of the DUT, an observed shift can be around or approximately 0.7%. See FIGS. 6-14. In one example, boxplots of actual test values are shown in FIGS. 13 and 14 for a particular DUT.

In particular, FIG. 5's exemplary boxplot display includes the following: an Outlier (*) 321—an observation that is beyond the upper or lower whisker (box plot's vertical line); an upper whisker (vertical line extending above a box in the box plot) 323—extends to a maximum data point within 1.5 box heights from the top of the box; an interquartile range box 325 representing a middle 50% of test data depicted by the box section including three significant sections consisting of a top line, middle line, and bottom line where: a top line—Q3 (third quartile) defining a top section of the boxplot section where 75% of the depicted DUT test data are less than or equal to this value; a middle line bisecting the box representing Q2 (median) depicting a 50% of the DUT test data are less than or equal to this value; a bottom line—Q1 (first quartile) depicting 25% of the test data are less than or equal to this value. FIG. 5 also shows a lower whisker (vertical line extending below the box 325 in the box plot) 327, which extends to a minimum data point within 1.5 box heights from the bottom of the box 325.

FIG. 6 shows an exemplary boxplot displaying a percentage change in initial measurements of an exemplary DUT at five hundred Hours by row. In particular, FIG. 6 shows data representing a row consisting of eight individual electrical circuit paths on the x-axis. On the y-axis is the percentage change in a signal proportional to a propagation delay response between an initial data and data acquired after five hundred hours of accelerated life testing. All rows in this example show a negative percentage shift. This example shows a first instance of multiple accelerated life testing data points which can be used to characterize aging effects on the exemplary DUT.

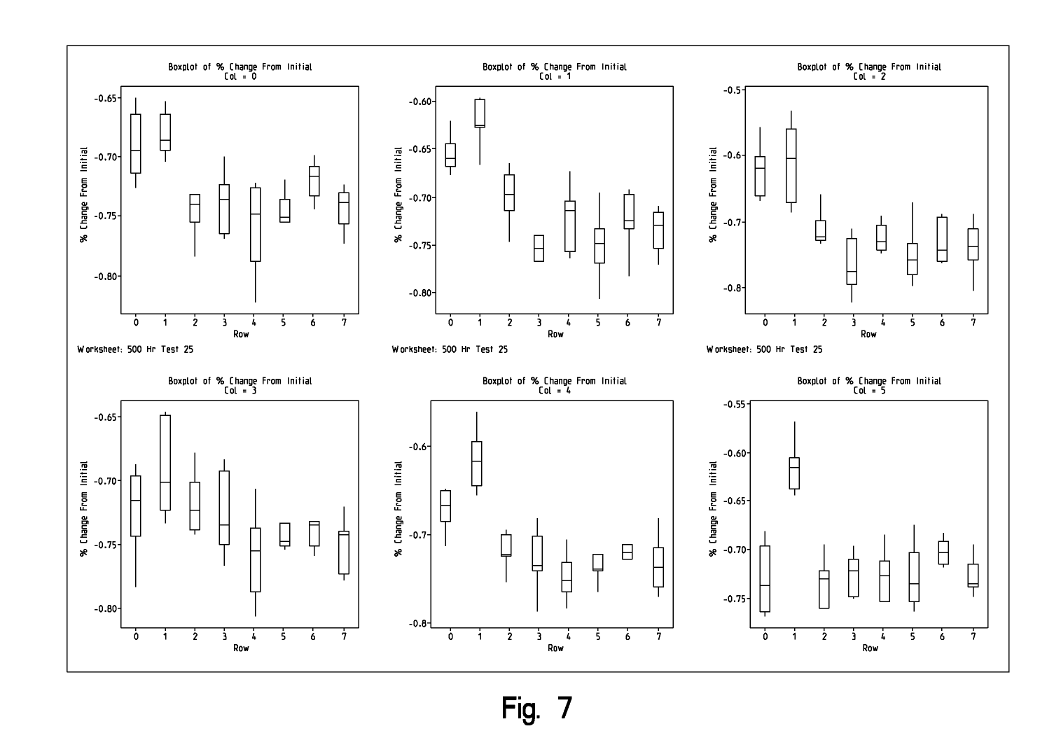

FIG. 7 shows an exemplary boxplot displaying a percentage change in initial measurement at five hundred hours by row (Columns 0-5 Separate). Circuits in each eight exemplary individual rows have differing numbers of transistors in a propagation delay path. A number of circuit elements effects a duty cycle in that longer signal paths have lower duty cycles. These exemplary circuits are exercised during accelerated life stressing conditions to better understand effects of circuit activity on device aging.

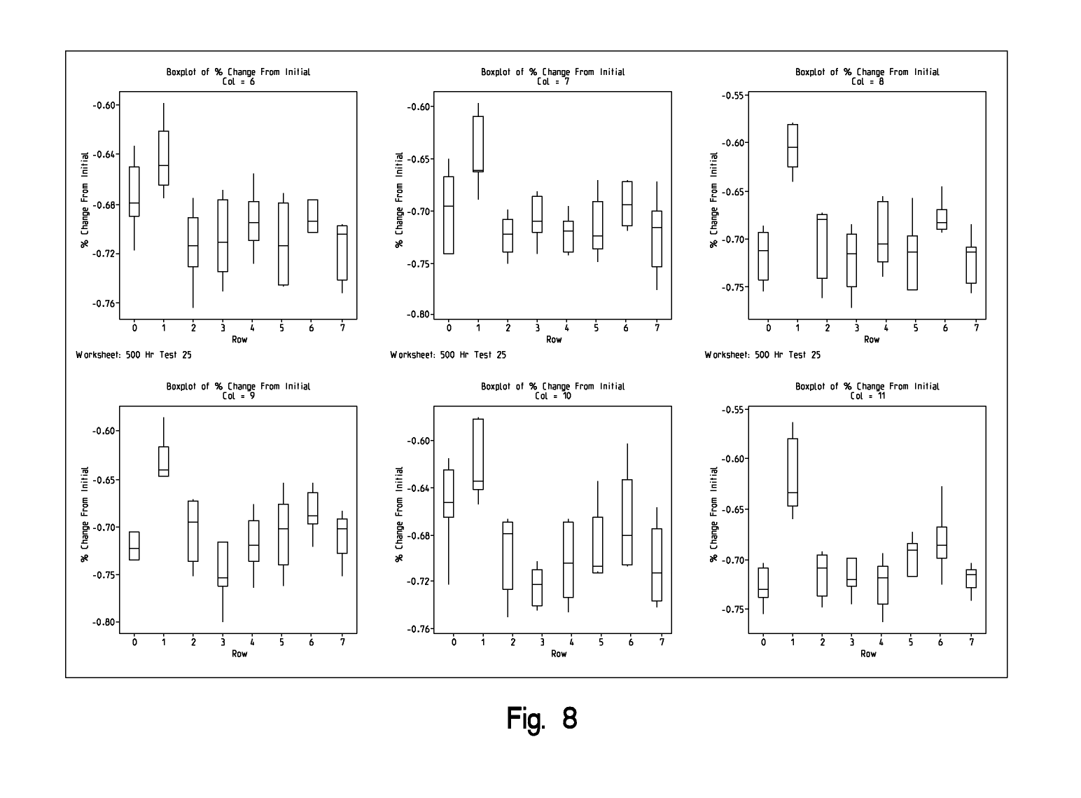

FIG. 8 shows an exemplary boxplot displaying percentage change in initial measurements at five hundred hours by row (Columns 6-11 Separate). Propagation delay evaluation circuit stimulation is repeated in multiple columns across an entire volume of an exemplary integrated circuit. This example provides data related to possible subtleties associated with the propagation evaluation circuit's physical location within the volume of the integrated circuit.

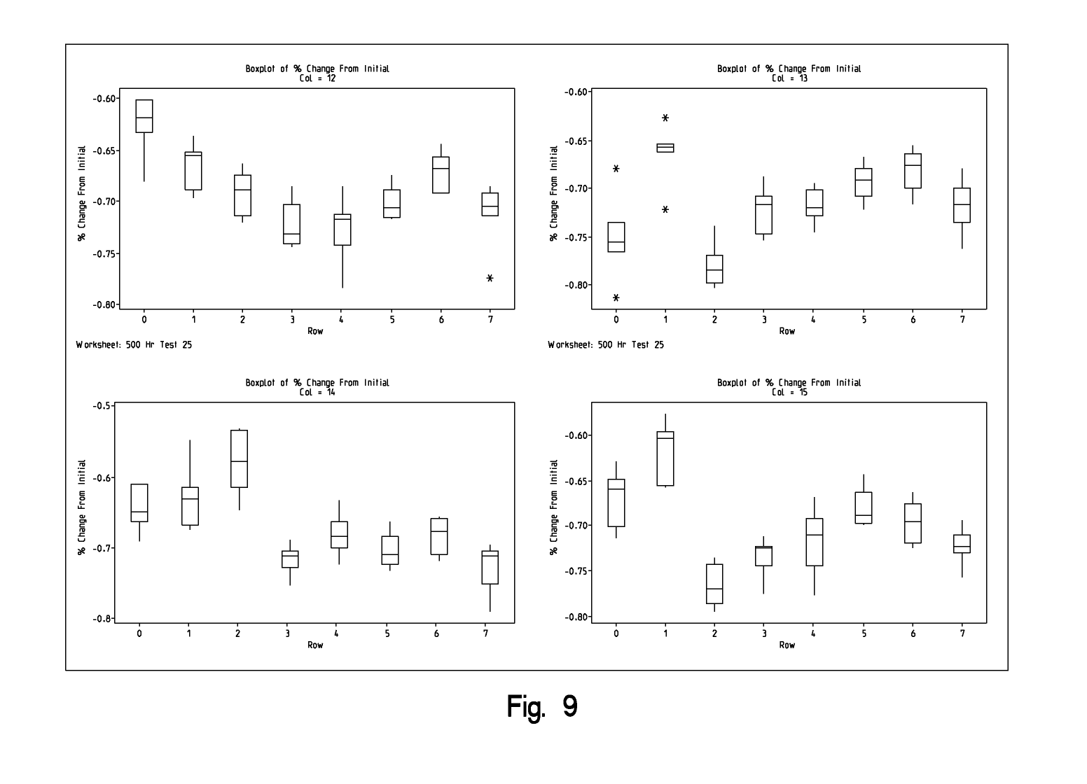

FIG. 9 shows an exemplary boxplot displaying percentage change in initial measurements at five hundred hours by row (Columns 12-15 Separate). Data from the various columns across the integrated circuit systematically demonstrate a percentage data shift in the range of −0.60% to −0.70%.

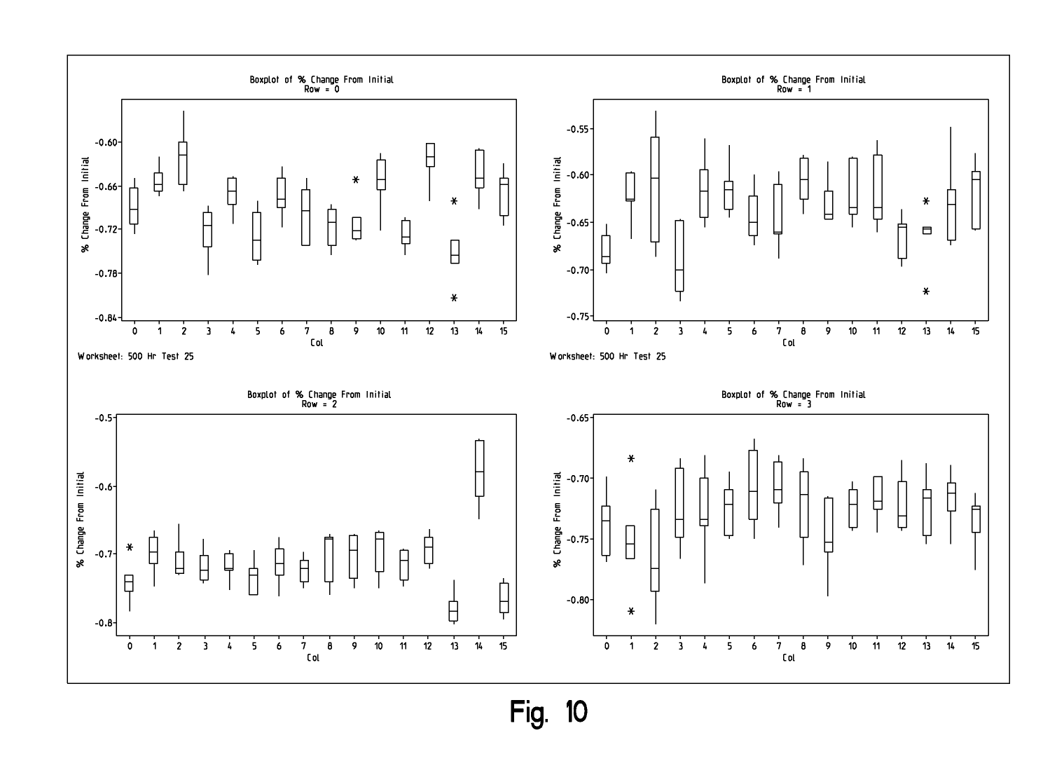

FIG. 10 shows an exemplary boxplot displaying percent change in initial measurements at five hundred hours by column (Rows 0-3 Separate). Propagation delay data can also be analysed per column, allowing characterization of proportional propagation delay data across circuits with a similar number of circuit elements.

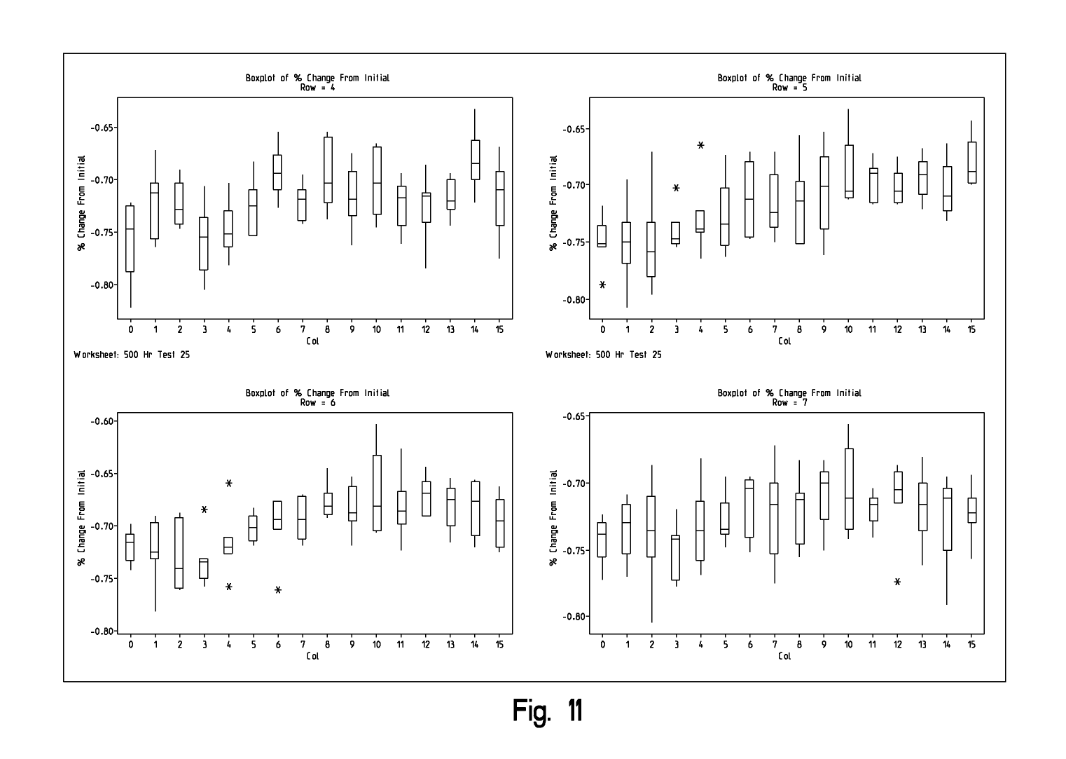

FIG. 11 shows an exemplary boxplot displaying percentage change in initial measurements at five hundred hours by column (Rows 4-7 Separate). Data can be analysed in various ways allowing more sensitive identification of circuits aging effects based on duty cycle, physical location and number of circuit elements. These analyses can be used for creating an understanding and identification of indicators of aging, which can be used to determine if a suspect integrated circuit is new or used.

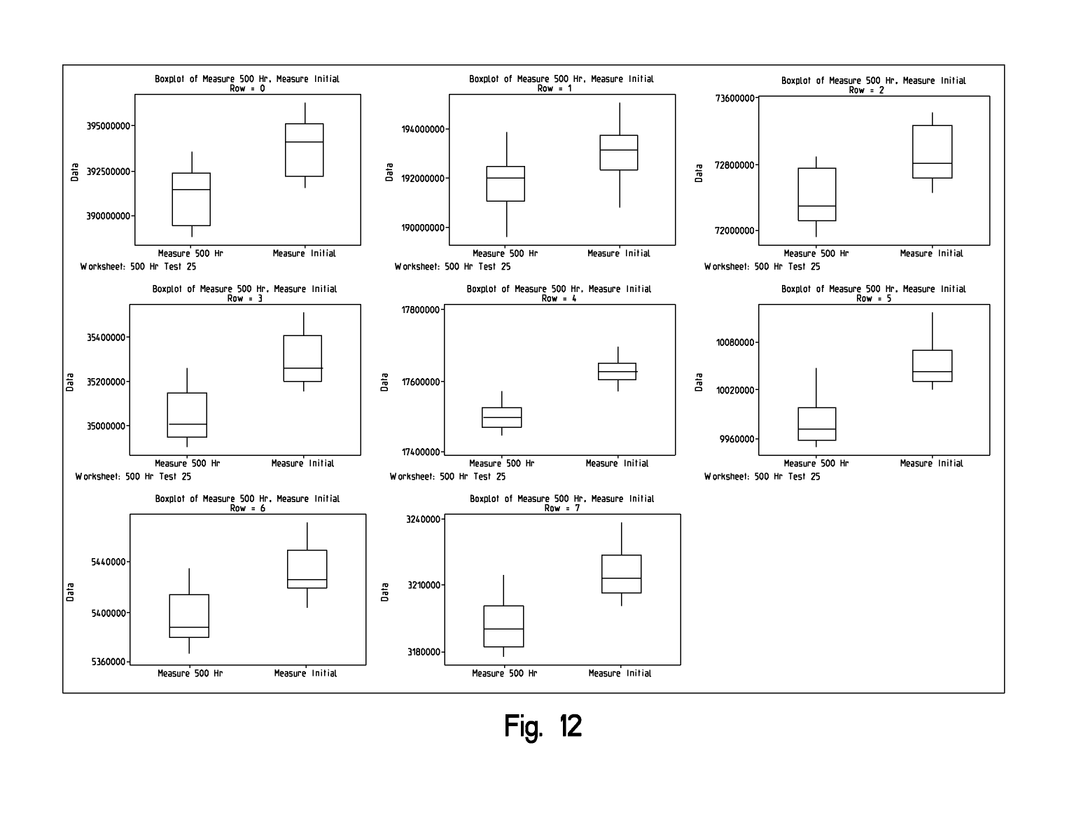

FIG. 12 shows an exemplary boxplot displaying five hundred hour measurements vs zero hour measurements. Measured frequency of operation is shown for the initial measurement and after five hundred hours of accelerated aging. This data demonstrates a decrease in the operational frequency of the circuits after aging. In these examples boxplots are used, but multiple analysis techniques can be used to include but not limited to Histograms, Trend Plots, Principal Component Analysis (PCA), Discriminant Analysis (DA), Neural Network Analysis, Traditional Statistical Analysis, Pattern Recognition and Histograms,

FIG. 13 shows an exemplary boxplot displaying a delta of five hundred hours minus zero hour measurements. Absolute frequency shift between initial and post 500 hours of age stressing can be seen per row. Each row has a different frequency response due to incorporating differing numbers of circuit elements in the propagation delay path.

FIG. 14 shows an exemplary delta of five hundred hour minus zero Hour Measurements by Column (Each Row Separate). Absolute frequency shift between initial and post five hundred hours of age stressing and be seen per row. Such analysis can be used to isolate circuit age related defects, failures, or discrepancies based on physical location across the integrated circuit's volume.

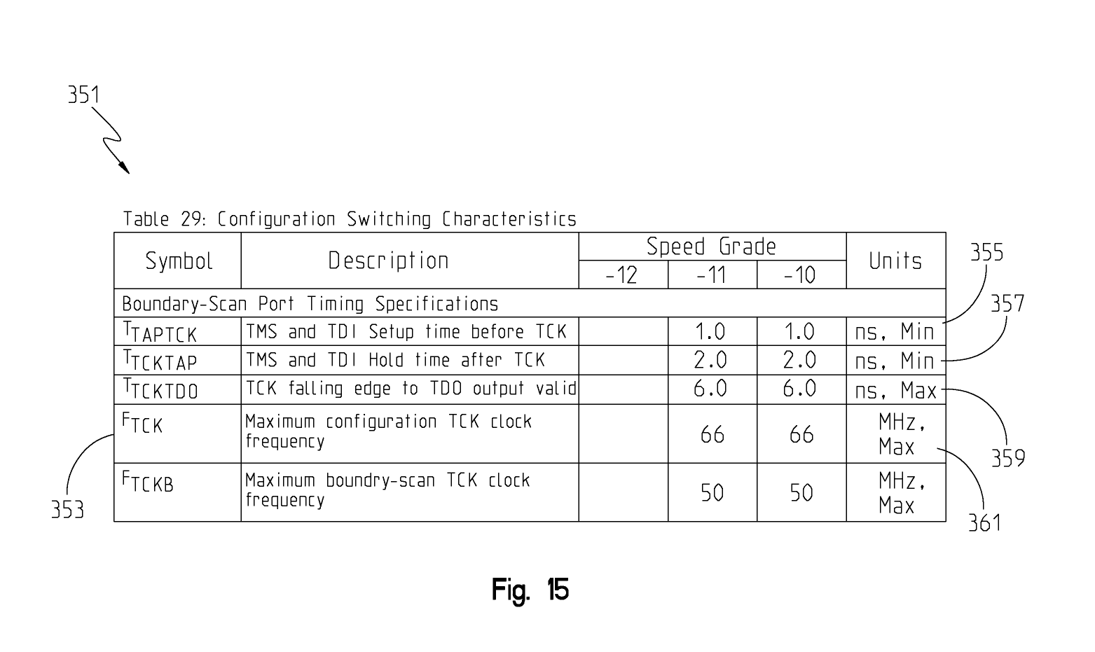

FIG. 15 shows a section of a typical manufacturer's specification data sheet 351 for a microelectronic component. The F_{TCK} 353 lists a Max frequency of 66 MHz 361. In practice the device does not cease to operate at the exact Max frequency, rather it operates beyond; often well beyond the listed Max frequency. The exact frequency at which the device will operate above and beyond the listed Max frequency can be used as an indicator of aging, previous usage, misrepresentation or an otherwise inferior product. An important aspect of obtaining a Max frequency is setting of timing parameters T_{TAPTCK} 355, T_{TCKTAP} 357 and T_{TCKTDO} 359 such that the timing is optimized to measure the actual Max frequency. To assist a Test Engineer in optimizations, Shmoo displays cab be used to quickly characterize data by providing visual representation of multi-parameter reference timing sweeps.

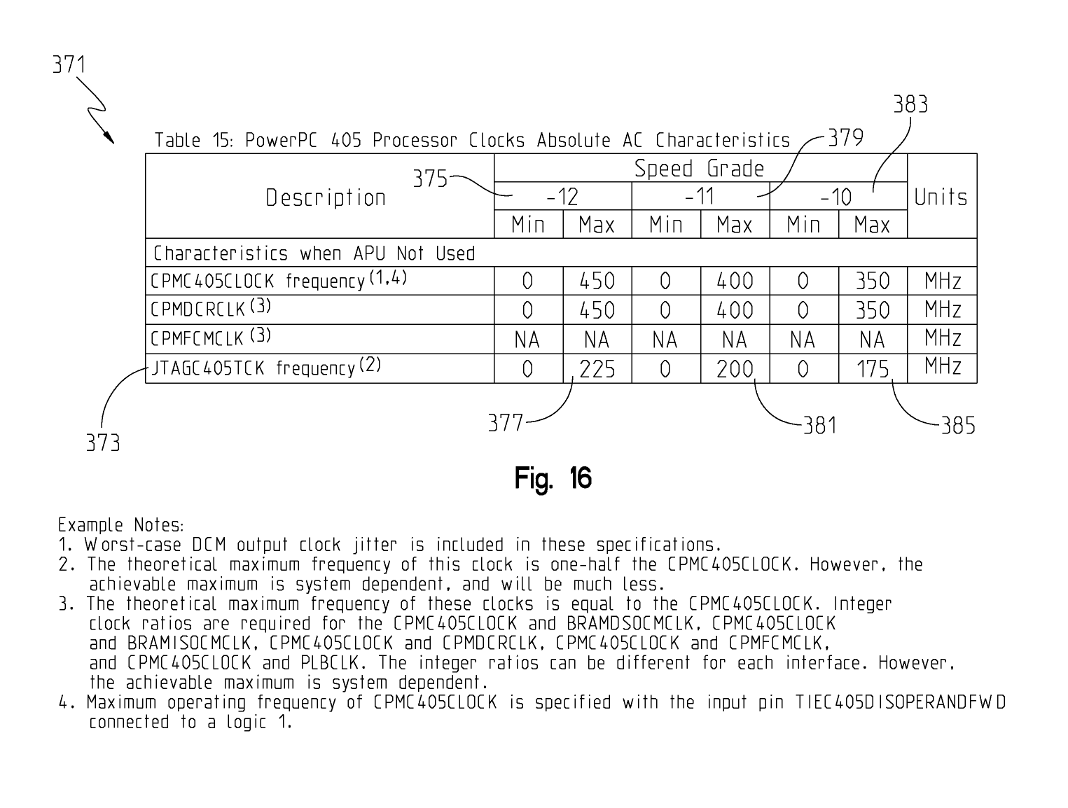

FIG. 16 shows an exemplary section of a typical manufacturer's specification data sheet 371 for a microelectronic component in which “speed binning” is used by the manufacturer to grade the components as to Max frequency for the selected parameter 373. In this example “−12” 375 has a Max of 225 MHz 377 whereas “−11” 379 has a Max of 200 MHz 381 and “−10” 383 has a Max of 175 MHz 385. One counterfeiting technique can include re-labelling components with a faster speed grade to increase the selling value. An exemplary proposed technique of overclocking could be used to evaluate for this relabeling condition. One aspect of an exemplary testing in accordance with the invention can include optimizing automatic test equipment (ATE) timing parameters so as to determine an actual Max frequency for a given parameter. An exemplary testing operation could entail ensuring selected parts meets a specification with sufficient margin, but does not necessarily push parameters such as Max T_{CLK} to an absolute limit of operation.

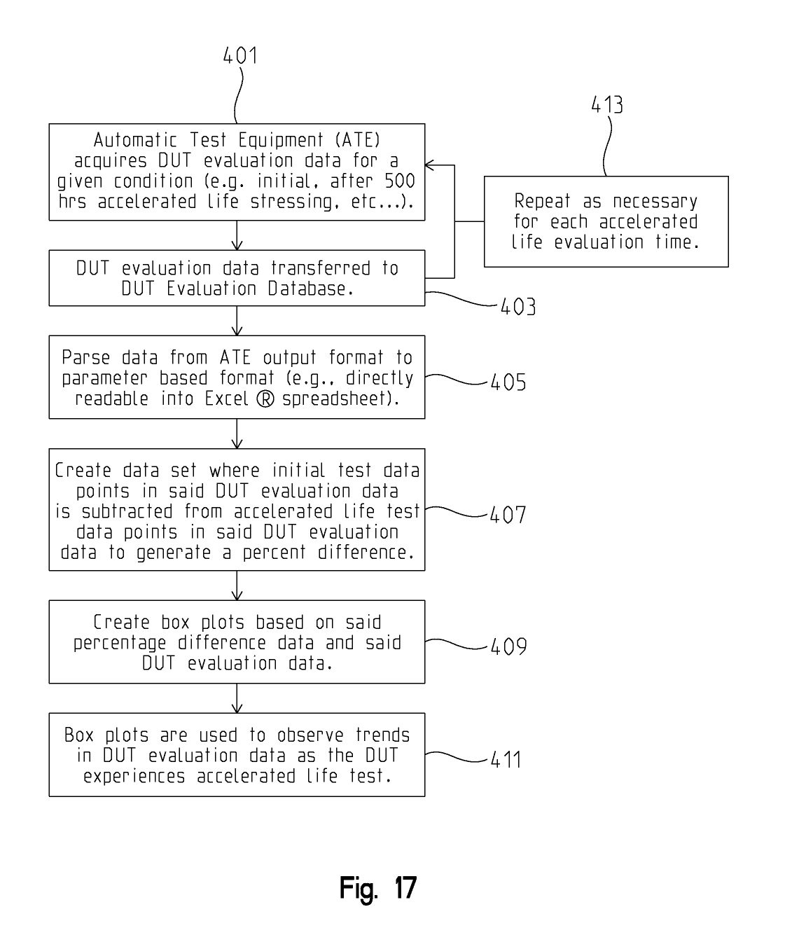

FIG. 17 shows an exemplary flow for creating boxplots. An ATE DUT test system is used to acquire DUT evaluation data 401. DUT data is acquired at various accelerated stress times 413. DUT evaluation data is transferred to DUT evaluation database 403. Data is processed to create boxplots 405, 407, 409, 411.

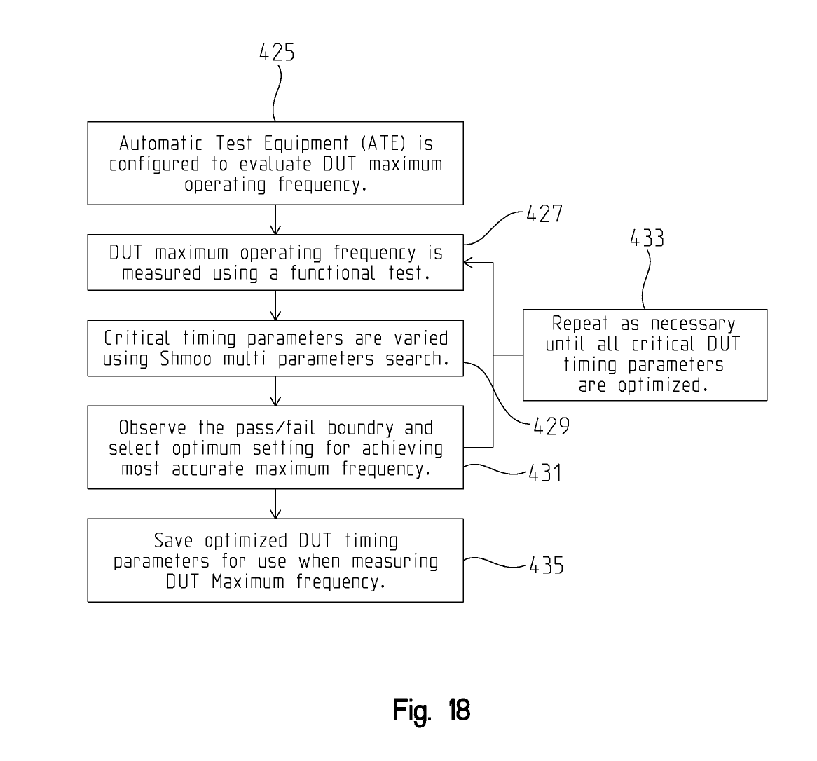

FIG. 18 shows an exemplary flow for using Shmoo diagrams to optimize timing for measuring DUT maximum operating frequency an ATE 425 is used to evaluate DUT maximum operating frequency. DUT critical timing parameters are optimized using, e.g., a Shmoo two-parameter search to optimize timing parameter values 427, 429, 431, 433. An exemplary two-parameter search can involve varying a clock frequency as the first parameter and varying an associated timing parameter as the second (e.g., parameters such as listed in FIG. 3, 355, 357 or 359).

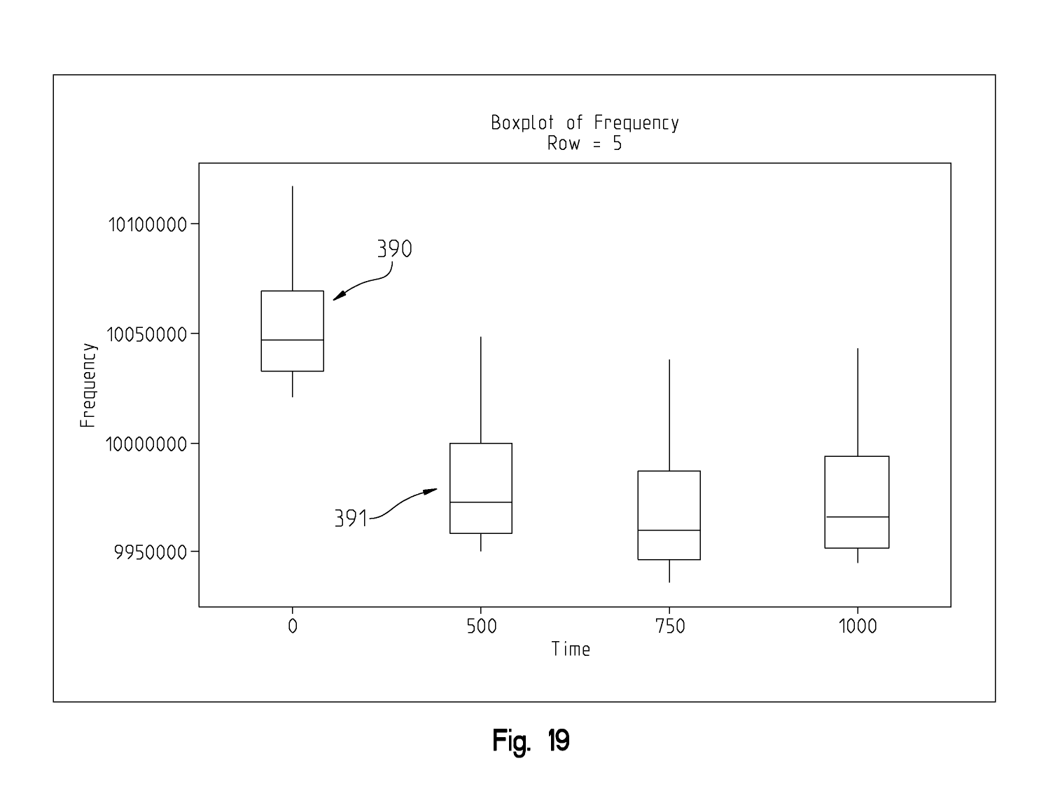

In another example, FIG. 19 shows a KGDUT test result where testing inputs to the KGDUT include a signal with a frequency of 10.05 MHz at time zero 390 which represents pre accelerated aging. After 500 cycles of accelerated aging 391, measured frequency has fallen below 10 MHz. In this example, there are two ways this data could be used to assist in detecting, e.g., used parts being sold as new.

Technique one can include a case where, if time zero frequency is known from measuring the KGDUT from a similar manufactures lot of parts, then a direct measurement of an unknown DUT (e.g., TADUT) can be made. If an exemplary unknown DUT (e.g., TADUT) measures below 10 MHz then based on post accelerated aging testing of the KGDUT the unknown DUT should be considered suspect (e.g., counterfeit).

Technique two can include, for example, a case where, if a lot of parts (e.g., unknown DUTs or TADUTS) arrive and there is no known good data available, the following can be done. Step 1, perform a baseline measurement of all the parts (e.g., unknown DUTs or TADUTS) to produce baseline data Step 2, select a part and perform a series of accelerated aging actions on the parts then perform testing of the parts after each accelerated aging action to create a plurality of analysis data associated respective part condition after each accelerated aging action. Step 3, analyse resulting testing data (baseline and analysis data associated with each said part condition) then determine if the analysis data and baseline measurement data display a shift between time zero and a predetermined number of hours or time (e.g., five hundred hours) associated with each step of accelerated aging action. Step 4, if the data shift is observed, use time zero data of the aged part as known good or KGDUT data; if the data shift is not observed, then resulting data (e.g, plurality of analysis data) cannot be used as known good data, but can be used to measure remaining lifetime for the part associated with testing by technique two. For remaining lifetime determinations, testing can include continuing to perform accelerated aging until a desired predicted lifetime is reached or the part (e.g., TADUT) fails. While not ideal, this does provide some insight into remaining lifetime in the part and resulting data set can be used to evaluate where the other parts fit on the aged part lifetime curve.

Although the invention has been described in detail with reference to certain preferred embodiments, variations and modifications exist within the spirit and scope of the invention as described and defined in the following claims.

1. A microelectronics counterfeit device screening method comprising:
clocking a first microelectronic device, artificially aging said first microelectronics device, and collecting first clocking data from a first plurality of signal interface points on said first microelectronics device;
overclocking said first microelectronic device, artificially aging said first microelectronics device, and collecting first overclocking data from said first plurality of signal interface points on said first microelectronics device;
clocking an unknown microelectronics device, and collecting second clocking data from a second plurality of signal interface points on said microelectronics device corresponding to said first plurality of signal interface points on said first microelectronics device;
comparing the first clocking data, second overclocking data, and second clocking data to determine if the unknown device correlates to one or more of a plurality of determinations comprising said unknown device conforms to a specification associated with said first microelectronic device, said unknown device was manufactured by an original equipment manufacturer, said unknown device was previously operated after manufacturing and testing but represented as unoperated after manufacturing and testing, or said unknown device has been subjected to damage or stress events exceeding one or more specification limits associated with one or more electro-mechanical specifications; and
producing an output showing said comparison.

2. A method as in claim 1, wherein said step of collecting said first clocking data, said first overclocking data, and said second clocking data is collected by multiple test detection and data collection/input sensors.

3. A method as in claim 1, wherein said step of comparing the first clocking data, second overclocking data, and second clocking data to determine if the unknown device correlates to one or more of a plurality of determinations comprising said unknown device conforms to a specification associated with said first microelectronic device includes inputting said data into one or more decision engines comprising a neural network, image recognition, statistical correlation tools, and decision trees.

4. A method as in claim 1, wherein said step of collecting said first clocking data, said first overclocking data, and said second clocking data comprises providing an electromagnetic (EM) sensors and data collection system adapted to sense and input said data into an a multiple mode analysis decision engine to evaluate said first microelectronic device to generate device unique EM signatures adapted to be used by a decision engine including a neural engine.

5. A method as in claim 1, wherein said damage or stress events comprises electrostatic discharge or thermal stress exceeding a predetermined threshold.

6. A method as in claim 1, wherein said first microelectronics device is a known-good device under test (KGDUT).

7. A method as in claim 1, wherein said comparing the first, clocking data, second overclocking data, and second clocking data comprises creating a plurality of Schmoo plots and determining a plurality of correlations within said Schmoo plots, said correlations comprise said step of determining if the unknown device correlates to said one or more of said plurality of determinations.

8. A method as in claim 1, wherein said output comprises a single pass/fail value comprising maximum frequency.

9. A method as in claim 1, wherein said output comprises an exemplary response from the first or second microelectronics device comprising a plurality of said data which organized in a Shmoo plot comprising a graphical display of a response of the first or second or second microelectronics device varying over a range of conditions and inputs including voltages, temperature, and refresh rates varied over said ranges and predetermined combinations of said conditions.

10. A method as in claim 10, wherein said range of conditions further comprises frequency, temperature, timing parameters, system- or component-specific variables, or varying test settings adjustable during fabrication of said first or second microelectronic device manufacturing or testing process.

11. A method for testing a device, comprising:
artificially aging a sample microelectronic device (SMD);
overclocking the SMD to SMD specification data and SMD maximum performance data;
collecting a first plurality of device data associated with said overclocking of each SMD;
repeating said artificially aging step, said overclocking step, and said collecting said first plurality of device data step at multiple aging data points over a predetermined aging progression of said SMD to generate a collection of said first device data;
overclocking a device under test (DUT) having at least part of a circuit portion contained in said SMD and collecting a second plurality of device data associated with the overclocked DUT, wherein said first and second plurality of device data are identical categories of device data;
comparing the first plurality of device data with said second plurality of device data to determine if said DUT correlates with one or more said aging data points of said predicted aging progression of said SMD or not; and
determining if said DUT has one or more first conditions based on said determination of a lack of correlation with said predicted aging progression, said one or more first conditions comprising:
the DUT does conform to a manufacturer's specification;
the DUT was not made by an original equipment manufacturer;
the DUT is used after a manufacturing and testing step but represented as unused after said manufacturing and testing step; or the DUT has been subjected to damage or stress events exceeding acceptable limits.

12. A method as in claim 11, wherein said damage or stress events comprises electrostatic discharge or thermal stress exceeding a predetermined threshold.

13. A method as in claim 11, wherein said SMD is a known-good device under test (KGDUT).

14. A method of testing an electronic device comprising:
providing a first automatic test equipment (ATE) and positioning said ATE to detect a plurality of electromagnetic signal information from a first device under test (DUT);
acquiring a first plurality of DUT test evaluation data from said first DUT based on said plurality of electromagnetic signal information, wherein at least some of said first plurality of DUT test evaluation data is each collected after application of one or more predetermined accelerated life stressing step of said first DUT in a sequence of said stressing steps adapted to simulate use or operation of said DUT or a damage event of said first DUT comprising electrostatic discharge or application of thermal stress exceeding a predetermined thermal parameter associated with said DUT;
storing said first plurality of DUT evaluation data in a DUT evaluation database;
creating a first data set produced by taking initial test data points from said plurality of DUT test evaluation data and subtracted them from at least some of said plurality of DUT test evaluation collected after said accelerated life stressing steps to generated a plurality of percent difference data;
creating a plurality of box plots based on said plurality of percent difference data; and
identifying at least one set of first condition indicator relationships in said plurality of DUT evaluation data as said DUT experiences accelerated life tests based on said box plots;
comparing the first condition indicator relationship data with a second plurality of DUT evaluation data associated with a second DUT to determine if said second DUT has an anomaly or undesirable condition, if the DUT conforms to a manufacturer's specification, if the DUT was made by an original equipment manufacturer, if the DUT has been previously subjected to a first operating condition comprising operation after manufacturing and testing, or the DUT has been subjected to damage or stress events exceeding predetermined limits.
